(19) United States
(12) Patent Application Publication
(10) Pub. No.: US 2008/0181035 A1
(43) Pub. Date: Jul. 31, 2008

(54) Method and system for a dynamically repairable memory

(76) Inventor: Atsushi Kawasumi, Kawasaki (JP)

Correspondence Address: SPRINKLE IP LAW GROUP, 1301 W. 25TH STREET, SUITE 408, AUSTIN, TX, 78705, US

(21) Appl. No.: 11/698,681

(22) Filed: Jan. 26, 2007

(51) Int. Cl. G11C 29/00; G11C 17/18

(52) U.S. Cl. 365/200; 365/225.7

(57) ABSTRACT

Systems and methods for a memory system capable of detection and repair of failures occurring during operation are disclosed. Embodiments of the present invention provide a memory system operable to detect an error at a memory cell of a memory and replace the failed memory cell. More specifically, in certain embodiments, a failure at a certain address of a memory may be detected during operation of the memory. This memory cell may then be replaced by a redundant memory cell. By replacing the failed memory cell the memory system may continue to be utilized without encountering subsequent errors due to the failed memory cell.

### TECHNICAL FIELD OF THE INVENTION

The invention relates in general to methods and systems for memory systems, and more particularly, to reparable memory systems. Even more particularly, the invention relates to memory systems which can account for failures detected during operation of a memory.

### BACKGROUND OF THE INVENTION

In recent years, there has been an insatiable desire for faster computer processing data throughputs because cutting-edge computer applications are becoming more and more complex. This complexity commensurately places ever increasing demands on microprocessing systems. These microprocessor systems have therefore been designed with hardware functionality intended to speed the execution of instructions.

One example of such functionality is the memory arrays utilized in conjunction with these microprocessor systems.

These memories have grown increasingly quick through the use of decreased margins (e.g. timing margin, temperature margin, etc.), and with the advent of newer manufacturing technologies, the number of memory gates within a specified area has increased dramatically. With these steady improvements in memories, however, have come a commensurate set of problems.

One of these problems is the failure of memory cells (e.g. a number of bits) within a memory (e.g. memory array). As memories grow denser and margins increasingly tight, the failure of memory cells increases as well. These failures may decrease the yield of memory circuits during manufacturing. To combat reduced yield of memory circuits, the concept of redundant memory was developed. Redundant memory cells, described succinctly, can be used to replace failed memory cells detected in a testing process. More specifically, memory circuits (e.g. memory chips or wafers) are designed to include a memory and a redundant memory. During a subsequent testing process when a failure is detected in cell (e.g. a bit, quarter word, half word, word, double word, any addressable size of a memory, etc. ) of the memory, that cell of memory may be replaced with a cell of the redundant memory. In other words, when the memory circuit is utilized any access to that cell of memory will instead access the cell of the redundant memory which has replaced that memory cell. In this manner, failures detected during a manufacturing and testing process can be detected and accounted for without having to scrap the memory circuit, improving yield.

During operation of these memories, however, further errors may occur for various reasons. These failures may arise from a whole host of causes including Negative Bias Temperature Instability (NBTI) or Hot Carrier Injection (HCI) and the number and location of these errors (e.g. occurring during operation of the memory circuit) may vary widely based on the utilization of a particular memory circuit. Thus, it is difficult, if not impossible, to detect, predict or account for these failures in the manufacturing process through the use of redundant memory.

To combat these operational failures Error Correcting Code (ECC) may be utilized during operation of a memory circuit. Even utilizing ECC logic, however, not all the failures may be corrected, for example if the number of failures exceeds the threshold for which the ECC is designed (number of bits, consecutive bits, etc.). To account for these operational errors, then, the margin of the memory circuit may be designed with margins which have built in tolerances to account for, or reduce, these possible failures. For example, by increasing the timing margin of memory gates the number of errors due to NBTI of HCI during operation of a memory circuit may be reduced. Not only do these increase margins result in slower memory circuitry, but in addition, may result in decreased yield of these memory circuits from the manufacturing process.

Thus, it is desired to be able to account for, or repair, failures in a memory which occur during the operation of that memory (e.g. a dynamically repairable memory), such that the margins of the memory circuit may be further reduced and a commensurate increase in the speed of a memory circuit achieved while simultaneously improving the manufacturing yield of the memory circuits. It is to these ends and needs, among others, that embodiments of the systems and methods of the present invention presented herein are directed.

### SUMMARY OF THE INVENTION

Systems and methods for a memory system capable of detection and repair of failures occurring during operation are disclosed. Embodiments of the present invention provide a memory system operable to detect an error at a memory cell of a memory and replace the failed memory cell. More specifically, in certain embodiments, a failure at a certain address of a memory may be detected during operation of the memory. This memory cell may then be replaced by a redundant memory cell. By replacing the failed memory cell the memory system may continue to be utilized without encountering subsequent errors due to the failed memory cell.

In one embodiment, an error in a cell of a memory may be detected during operation of the memory, the location of this memory cell determined and cell of the memory replaced with a cell of a redundant memory.

In an embodiment, the memory comprises a set of memory cells, the redundant memory comprises a set of redundant memory cells and there is logic operable to detect an error in the set of memory cells and memory replacement logic which can obtain the location of the cell and associate the location with a redundant memory cell of the set of redundant memory cells.

In another embodiment, the ECC logic may detect the error.

In other embodiments, the association may be accomplished using a redundancy fuse.

Embodiments of the present invention may provide the technical advantage that failures in a memory may be dynamically accounted for and repaired. This ability may in turn, result in increased yield of the manufacturing process of such a memory while simultaneously allowing the margins (e.g. timing, voltage, etc.) to be reduced resulting in a speedier and more robust memory system.

These, and other, aspects of the invention will be better appreciated and understood when considered in conjunction with the following description and the accompanying drawings. The following description, while indicating various embodiments of the invention and numerous specific details thereof, is given by way of illustration and not of limitation. Many substitutions, modifications, additions or rearrangements may be made within the scope of the invention, and the invention includes all such substitutions, modifications, additions or rearrangements.

### BRIEF DESCRIPTION OF THE DRAWINGS

The drawings accompanying and forming part of this specification are included to depict certain aspects of the invention. A clearer impression of the invention, and of the components and operation of systems provided with the invention, will become more readily apparent by referring to the exemplary, and therefore nonlimiting, embodiments illustrated in the drawings, wherein identical reference numerals designate the same components. Note that the features illustrated in the drawings are not necessarily drawn to scale.

FIG. 1 includes a flow diagram for one embodiment of a method for dynamically repairing a memory.

FIG. 2 includes a block diagram of one embodiment of a dynamically repairable memory.

FIG. 3 includes a flow diagram for one embodiment of a method for dynamically repairing a memory.

FIG. 4 includes a block diagram of one embodiment of a dynamically repairable memory.

### DETAILED DESCRIPTION

The invention and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the invention in detail. Skilled artisans should understand, however, that the detailed description and the specific examples, while disclosing preferred embodiments of the invention, are given by way of illustration only and not by way of limitation. Various substitutions, modifications, additions or rearrangements within the scope of the underlying inventive concept(s) will become apparent to those skilled in the art after reading this disclosure.

Reference is now made in detail to the exemplary embodiments of the invention, examples of which are illustrated in the accompanying drawings. Wherever possible, the same reference numbers will be used throughout the drawings to refer to the same or like parts (elements).

Attention is now directed to systems and methods for a memory system capable of detection and repair of failures occurring during operation (e.g. dynamically repairable). Embodiments of the present invention provide a memory system operable to detect a failure (e.g. error) at a memory cell of a memory and replace the failed memory cell. More specifically, a failure at a certain address of a memory may be detected during operation of the memory. This memory cell may then be replaced by a redundant memory cell (e.g. a cell of a redundant memory). By replacing the failed memory cell the memory system may continue to be utilized without encountering subsequent errors due to the failed memory cell.

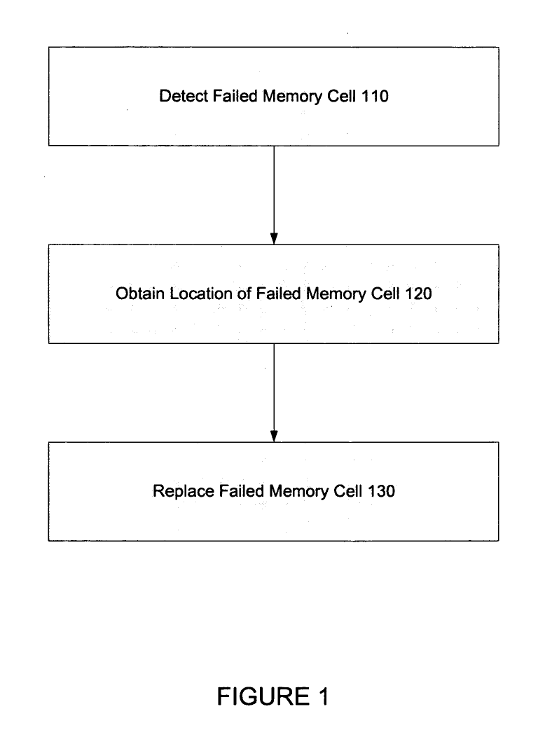

FIG. 1 depicts one embodiment of a flow diagram of just such a methodology for detecting and replacing failed memory cell. At step 110 a failure in a memory cell (e.g. a cell where an error has occurred) is detected during operation of the memory and the location of the failed memory cell obtained at step 120. The memory cell where a failure was detected at step 110 can then be replaced at step 130 (e.g. accesses to the address corresponding to the memory cell directed to a functioning memory cell) using the location obtained at step 120.

More specifically, in one embodiment, during operation of a memory a failure may be detected in a memory cell at step 110. This failure may be detected by proprietary logic or by error correcting code (ECC) logic for use with the memory. Thus, a memory cell may be detected as failed if the ECC logic detects a bit error in data read from the memory cell. In many cases, however, ECC logic may be operable to correct for errors occurring in one or more bits of a memory cell. Consequently, in certain embodiments a memory cell may be detected, or deemed, as failed if the number of bit errors detected by the ECC exceeds a threshold level, where the ECC logic is operable to correct for a number of bit errors equal to, or less than, that threshold level. Those of ordinary skill in the art will appreciate that various embodiments of ECCs will have different limitations and designs and that memory cells may be detected as failed (e.g. as having an error) according to a wide variety of different criteria depending on the type of ECC logic used in conjunction with a particular embodiment of the present invention.

Once a memory cell is detected as failed at step 110, however, the location of the failed memory cell may be obtained at step 120. As ECC logic may only be operable to detect that the data read from a memory cell has one or more bit errors, in one embodiment, the address corresponding to the memory cell may be written to an address register when the memory cell is accessed. This address register may or may not be part of the memory system and may, for example, be a register of associated logic utilizing the memory. Thus, when the ECC logic detects that a failure has occurred (e.g. the number of bit errors detected in data read from the memory cell exceeds a threshold level) the location of the memory cell where the failure was detected (e.g. the location being accessed when a failure was detected in the memory cell) may be obtained by reading from this address register.

Using the location of the failed memory cell (e.g. the location being accessed) obtained at step 120, the failed memory cell may be replaced as step 130. In one embodiment, this replacement may be realized by using the address obtained in step 120 to replace the failed memory cell with a cell of a redundant memory (e.g. such that access to the address will access a redundant memory cell instead of the failed memory cell). More specifically, this replacement may be effected by configuring a fuse for the redundant memory using the address obtained at step 120. Particularly, in one embodiment, a redundancy fuse may be burned or blown using the address obtained at step 120 to associate the address with a redundant memory cell such that access to the address accesses the associated redundant memory cell instead of the failed memory cell, replacing the failed memory cell with a redundant memory cell.

The redundancy fuse may, in one embodiment, be an e-fuse such that by applying a certain threshold voltage (or higher) these fuses may be burned or blown. Thus, using the address obtained at step 120, the redundancy fuse may be burned by applying at least the threshold voltage level to the fuse so access to the address will access a cell of a redundant memory instead of the failed memory cell. In conjunction with the replacement of the failed memory cell, access to the memory system may or may not be temporarily suspended for a certain period of time, which may be sufficient to allow the failed memory cell to be replaced (e.g. the redundancy fuse to be burned such that access to the address access a redundant memory cell). The replacement may also occur when the memory system is idle without suspension of access to the memory system, or may take place without effecting the operation of the memory system. The particulars of the replacement of a memory cell will vary depending on the particular embodiment of the invention utilized and the corresponding system(s) with which the particular embodiment is utilized (e.g. the associated logic which may utilize the memory system during operation).

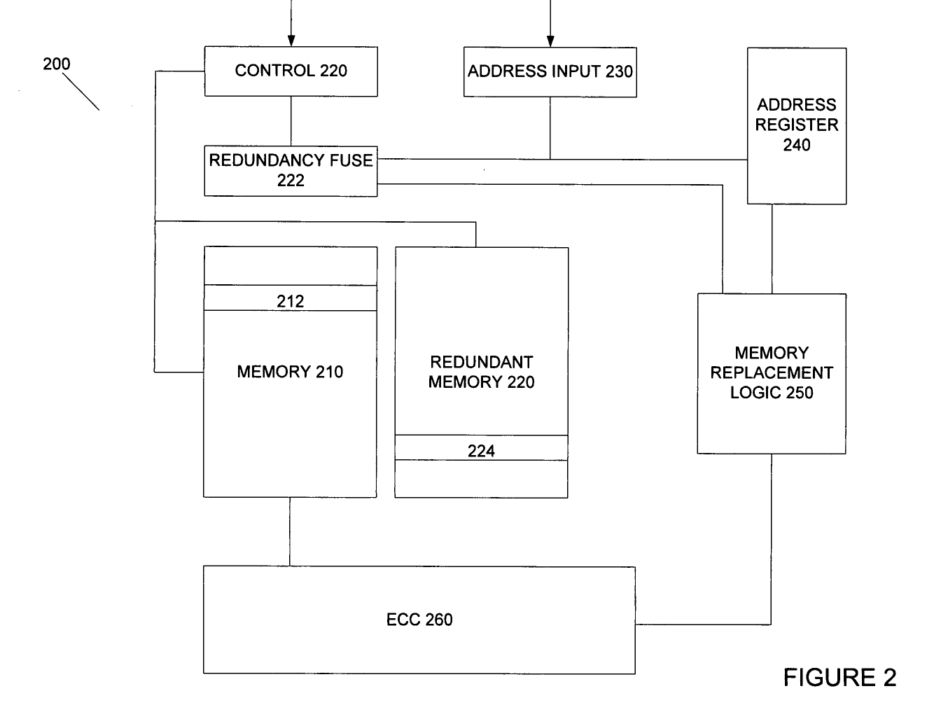

The systems and methods of the present invention may be better understood with reference to specific embodiments. To that end, FIG. 2 depicts a block diagram of one embodiment of a system for a dynamically repairable memory. Memory system 200 may include memory 210 (e.g. an array of memory cells), redundant memory 220, redundancy fuse 222, control logic 220, address register 240, ECC 260 and memory replacement logic 250. During operation associated logic (e.g. logic utilizing memory system 200, not shown) may access memory system 200 by providing an address to be accessed at address input 230 and associated control information to control logic 220. The accessed address may be stored in address register 240 and the memory cell referred to by the address (which may be a cell of memory 210 or memory 220 depending on the state of redundancy fuse 222) may then be accessed according to the control information.

When a memory cell from memory 210 is read, the set of bits read from the memory cell may be provided to ECC logic 260, which may determine if the set of bits comprises an error (e.g. using a check bit memory array, not shown) and correct for the error, if possible. If the number of errors in the set of bits exceeds a threshold level (as discussed above), ECC logic 260 may indicate that a memory cell failure has occurred to memory replacement logic 250. Memory replacement logic 250 may then obtain the address of the failed memory cell (e.g. the address accessed which generated the set of bits causing ECC logic 260 to indicate a failed memory cell) from address register 240, and cause redundancy fuse 222 to be configured (e.g. burned or blown) such that a subsequent access to that address will access a memory cell of redundant memory 220 (e.g. a redundant memory cell).

In one embodiment, memory replacement logic 250 may cause the configuration of redundancy fuse 222 while memory system 200 is idle, or during configuration of redundancy fuse 222, memory replacement logic 250 may cause access to memory system 200 to be suspended. In this manner, a cell of memory 210 may effectively be dynamically replaced by a cell of redundant memory 220 (e.g. while memory system 200 is substantially in operation or being utilized in conjunction with associated logic, as opposed to during manufacture of memory system 200).

It may be helpful to illustrate the operation of memory system 200 with reference to a specific example. Suppose associated logic (not shown) utilizing memory system 200 requests a read from address 0x04 corresponding to memory cell 212 of memory 210. The address 0x04 is stored in address register 240, following which data is read from memory cell 212 and checked by ECC logic 260. At this point ECC logic 260 detects an error in the data read from memory cell 212, and thus indicates a memory cell failure to memory replacement logic 250. Memory replacement logic 250 receive a signal from ECC 260 that a memory cell has failed, obtains the address 0x04 from address register 240 and configures redundancy fuse 222 such that subsequent accesses to address 0x04 correspond to redundant memory cell 224 of redundant memory 220. Thus, when address 0x04 is next read or written (or other access performed) data will be read from, or written to, redundant memory cell 224.

Nowadays, however, memory circuits have becomes so sensitive that they are subject to soft errors caused by cosmic rays, alpha particles, etc. Passage of ionized particles through a memory circuit may cause a disturbance significant enough to flip one or more bits of data stored in a memory cell. Though this soft error may result in incorrect data, and thus ECC logic 260 indicating that a memory cell has failed, in truth no permanent damages remains in the structure of the memory circuitry and the memory cell is thereafter completely reusable for storing data without error. With the scaling down of device sized and operation voltage these types of soft errors are occurring more frequently. Thus, it may be desirable to account for these soft errors in embodiments of the present invention. As the probability of these soft errors occurring in the same memory cell more than once is small, to account for these soft errors then, embodiments of the present invention may replace a memory cell of a memory only when a threshold number of errors (either consecutive or non-consecutive) have occurred in a memory cell, such that it is substantially probable that the error in the memory cell was not caused by a soft error.

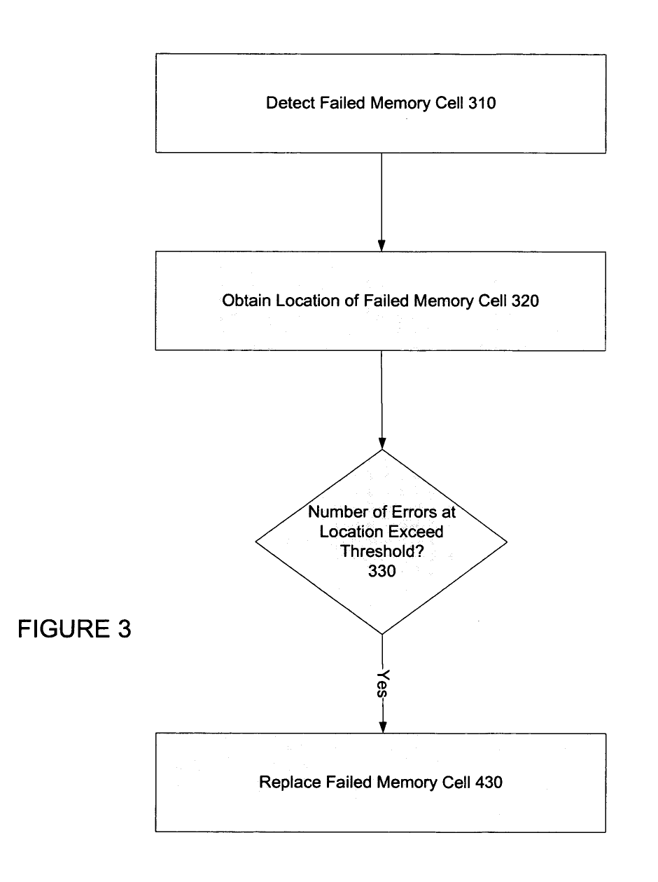

FIG. 3 depicts one embodiment of a flow diagram of just such a methodology for detecting and replacing failed memory cell while taking into account soft errors which may occur during operation of the memory system. At step 310 a failed memory cell is detected during operation of the memory and the location of the failed memory cell obtained at step 320. It can then be determined if the number of errors at the failed memory cell exceeds a threshold level at step 330. If the error threshold is exceeded at step 330, the memory cell where a failure was detected at step 310 can then be replaced at step 340 (e.g. access to the memory cell redirected to a functioning memory cell) using the location obtained at step 320.

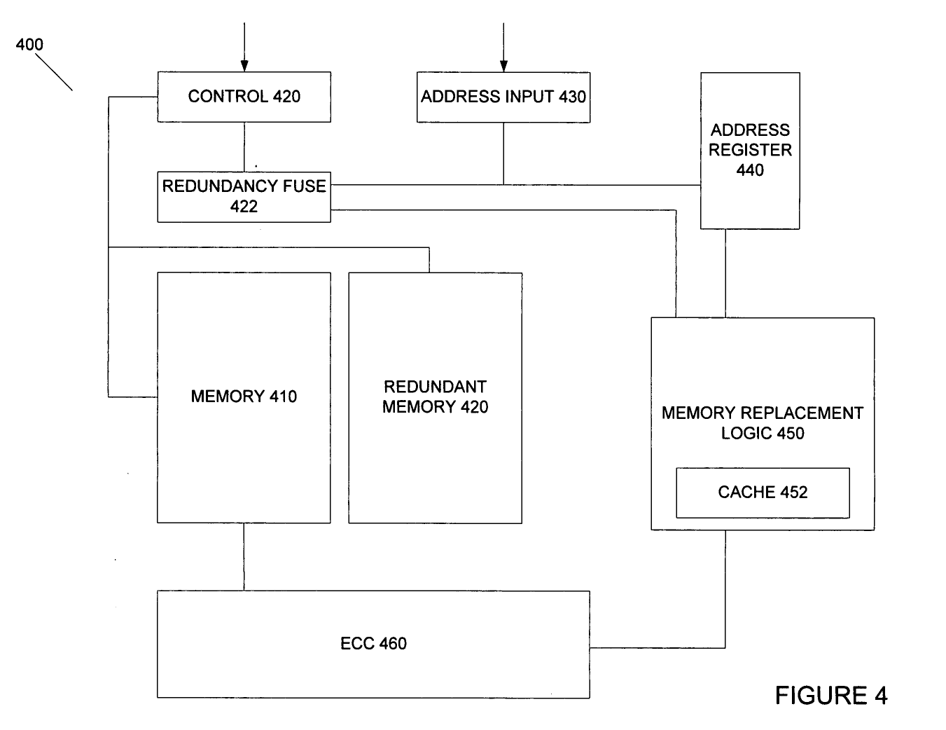

Moving now to FIG. 4, a block diagram of one of one embodiment of a system for a dynamically repairable memory which may be operable to replace a memory cell after a threshold number of errors is depicted. Memory system 400 may include memory 410 (e.g. an array of memory cells), redundant memory 420, redundancy fuse 422, control logic 420, address register 440, ECC 460 and memory replacement logic 450 including storage such as cache 452. During operation associated logic (e.g. logic utilizing memory system 400, not shown) may access memory system 400 by providing an address to be accessed at address input 430 and associated control information to control logic 420. The accessed address may be stored in address register 440 and the memory cell referred to by the address (which may be a cell of memory 410 or redundant memory 420 depending on the state of redundancy fuse 422) may then be accessed according to the control information.

When a memory cell from memory 410 is read, the set of bits read from the memory cell may be provided to ECC logic 460, which may determine if the set of bits comprises an error (e.g. using a check bit memory array, not shown) and may correct for the error, if possible. If the number of errors in the set of bits exceeds a threshold level (as discussed above), ECC logic 460 may indicate that the memory cell is failed to memory replacement logic 450. Memory replacement logic 450 may then obtain the address of the failed memory cell (e.g. the address accessed which generated the set of bits causing ECC logic 460 to indicate that a memory cell has failed) from address register 440.

Cache memory 452 may store a set of addresses, where an error has previously occurred at the memory cell corresponding to the address (e.g. the memory cell corresponding to the address was previously indicated as a failed memory cell by ECC logic 460). Thus, memory replacement logic 450 may compare the address obtained from address register 440 to the addresses stored in cache 452. If a matching address is found in cache 452 this indicates that an error has previously occurred at the memory cell corresponding to the address. Memory replacement logic 450 may then cause redundancy fuse 422 to be configured (e.g. burned or blown) such that a subsequent access to that address will access a memory cell of redundant memory 420 (e.g. a redundant memory cell), as discussed above.

If, however, a matching address is not found in cache 452, the address obtained from address register 440 may be added to cache 452, such that if a subsequent error occurs in the memory cell corresponding to the address it can be determined that multiple errors have occurred at the memory cell corresponding to that address and that memory cell replaced.

It should be noted here that various cache management schemes may be utilized in conjunction with various embodiments of the present invention. For example, different replacement policies (e.g. least recently used (LRU)) may be utilized with respect to determining which entries to replace in cache 452, and that after it has been determined that multiple errors have occurred in a memory cell corresponding to an address, and that memory cell replaced with a redundant memory cell, the entry in cache 452 corresponding to that address may be removed, marked for first replacement, flushed, etc.

It should also be noted that various cache arrangements may also be utilized in conjunction with different embodiments. For example, in one embodiment an entry in a cache may be associated with an accumulator in the cache such that the accumulator may be incremented to indicate the number of errors occurring in conjunction with a particular address such that the memory cell corresponding to that address may be replaced which the number of errors exceeds a certain threshold. In another embodiment, a cache entry may have an address and associated timestamp, such that after an address has been in the cache for a certain length of time without a repeat error occurring at a memory cell associated with the address the entry may be flushed, or marked for replacement, etc. Cache 452 may also be a set of one bit entries indexed by a hashing the address, such that an obtained address may be utilized to index into the cache and if the cache entry corresponding to the address is set, a previous error has been detected for that address, etc.

In this manner, a cell of memory 410 may effectively be dynamically replaced by a cell of redundant memory 420 and soft errors occurring in memory 410 accounted for as well. An appropriate cache arrangement, management scheme, size and other parameters of the cache may be determined based on the memory system with which the cache is to be utilized and the associated logic which is to utilize the memory system with which the cache is utilized.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component of any or all the claims.

What is claimed is:

1. An dynamically repairable memory system, comprising:
a memory comprising a set of memory cells;
a redundant memory comprising a set of redundant memory cells;
logic operable to detect an error in data from a first memory cell of the set of memory cells during operation of the memory system; and
memory replacement logic operable to obtain a location of a first memory cell and configure the memory system such that the location is associated with a first redundant memory cell of the set of redundant memory cells.

2. The system of claim 1, further comprising a redundancy fuse, wherein configuring the memory system comprises blowing the redundancy fuse.

3. The system of claim 2, wherein the logic operable to detect an error is Error Correcting Code (ECC) logic.

4. The system of claim 3, wherein the ECC logic is operable to signal the memory replacement logic that the error was detected.

5. The system of claim 4, wherein the location is an address.

6. The system of claim 5, further comprising an address register operable to store the address when the address is accessed.

7. The system of claim 6, wherein the address is obtained from the address register and the redundancy fuse is blown to associate the address with the first redundant memory cell.

8. The system of claim 7, wherein the memory replacement logic comprises storage and the memory replacement logic is operable to determine if a previous error occurred at the first memory cell.

9. A method for dynamically repairing a memory; comprising:
detecting an error in a first memory cell of a memory during operation of the memory;
obtaining a location associated with the first memory cell; and
associating a first redundant memory cell with the location, such that subsequent accesses referencing the location will access the redundant memory cell.

10. The method of claim 9, wherein associating the first redundant memory cell with the location comprises blowing a redundancy fuse.

11. The method of claim 10, wherein the error is detected using Error Correcting Code (ECC) logic.

12. The method of claim 11, wherein the ECC logic is operable to signal memory replacement logic that the error was detected.

13. The method of claim 12, wherein the location is an address.

14. The method of claim 13, wherein associating a first redundant memory cell with the location comprise accessing an address register operable to store the address.

15. The method of claim 14, wherein the redundancy fuse is blown to associate the address with the first redundant memory cell.

16. The method of claim 15, comprising determining if a previous error occurred at the first memory cell.
